(19) United States
(12) Patent Application Publication
(10) Pub. No.: US 2025/0291328 A1
(43) Pub. Date: Sep. 18, 2025

(54) METHOD, SYSTEM AND APPARATUS FOR TEACHING AND VERIFYING END STATION

(71) Applicant: Axcelis Technologies, Inc., Beverly, MA (US)

(72) Inventor: Chiusheng Wu, Beverly, MA (US)

(21) Appl. No.: 19/053,283

(22) Filed: Feb. 13, 2025

Related U.S. Application Data
(60) Provisional application No. 63/564,841, filed on Mar. 13, 2024.

(51) Int. Cl. G05B 19/402

(52) U.S. Cl. CPC G05B 19/402; G05B 2219/39246

(57) ABSTRACT

The disclosure generally relates to a robotic system for positioning a workpiece relative to certain machinery. In one embodiment, the disclosure relates to a method, system and apparatus to teach positioning robots to place a workpiece relative to a processing center such as a chuck and to verify the placement using geometrical relationship therebetween. In one embodiment, the disclosure relates to an apparatus to position a workpiece at a chuck of a processing station. The apparatus includes a memory circuitry comprising an executable code; a central processing unit (CPU) in communication with the memory circuitry; an end effector (EE) for grasping and relocating the workpiece as well as an alignment chuck and a processing chuck. The alignment chuck and the wafer may be used to determine the distance between the chuck's center location (E) and the workpiece's center using various geometric relationships.

The Instant application claims the filing date benefit and priority to the Provisional U.S. Patent Application Ser. No. 63/564,841, filed Mar. 13, 2024 (“the '841 Application”) and entitled Method. System and Apparatus for Teaching and Verifying End Station. The '841 Application is incorporated herein in its entirety.

### FIELD

The disclosure generally relates to a robotic system for positioning a workpiece relative to certain machinery. In one embodiment, the disclosure relates to a method, system and apparatus to teach positioning robots to place a workpiece relative to a processing center such as an electrostatic chuck.

### BACKGROUND

Conventional transport robot teaching methods rely on sensor, cameras and fixtures placed inside and/or outside of the substrate processing chamber. Given that the substrate processing chamber may be operated under vacuum and often at a significantly elevated temperature, such placements are not often feasible or cost effective. In some instances, such modifications require extensive modifications to the existing instrument. Thus, there is a need for a method, system and apparatus for auto teaching a robotic arm for waver processing.

### SUMMARY OF THE DISCLOSURE

The disclosed embodiments relate to a method, system and apparatus to teach positioning robots to place a workpiece relative to a processing center and to verify the correct placement.

In one embodiment, the disclosure relates to applying the geometric relationships between a substrate (i.e., workpiece wafer) and an aligner's chuck to find eccentricity. It is assumed that the aligner's chuck has substantially the same relative geometric center location as the geometric center of the electrostatic chuck (E). Thus, by aligning the workpiece to be concentric with the aligner's center, the workpiece would necessarily align concentrically with the electrostatic chuck's center (E). As used herein, eccentricity is a measure of the distance between the wafer center and the chuck center. The term “offset” refers to a fraction (e.g., half) of the eccentricity value and it also denotes the distance between a workpiece's geometric center and the electrostatic chuck center (E).

Once calculated, the eccentricity (“Eccen.”) value may be used to determine the geometric center location (E) of an electrostatic chuck residing at a processing chamber. The calculation may be used to train the moving equipment (i.e., robots) to place subsequent workpieces at the same center location (E). In another embodiment, the information is used to verify placement and to confirm placement accuracy of wafer handling components including atmospheric robots and vacuum robots. In still another embodiment, the disclosed principles relate to using an aligner to determine the resolution of the wafer handling system.

An exemplary embodiment of the disclosure is directed to an apparatus to position a workpiece at a repeatable location of a processing station chuck. In one implementation, the disclosure relates to a system to position a substantially circular workpiece at a center location (E) of an electrostatic chuck. The apparatus may comprise: one or more memory circuits comprising an executable code; one or more central processing units (CPU) in communication with the memory circuits, the one or more CPUs configured to execute the code, causing the system to: place the workpiece at a first position on the chuck to determine a first workpiece center location (W₁) with respect to the chuck's geometric center location (E); rotate the workpiece by an angle (θ) in relation to the center location (E) to identify a first counter location (W₁′), the distance between W₁ and W₁′ defining a first Eccentricity (Eccen. #1); relocate the workpiece to a second position at a predefined distance (ΔR) from W; to thereby identify a second workpiece center location (W₂); rotate the workpiece by the angle (θ) in relation to the chuck's center location (E) to identify a second counter location (W₂′), the distance between W₂ and W₂′ defining a second Eccentricity (Eccen. #2); calculate the chuck's center location (E) as a function of one or more of W₁, W₂, Eccen. #1 and Eccen. #2.

Another exemplary embodiment of the disclosure relates to a non-transitory machine-readable medium with instructions stored thereon that when executed, the instructions cause a programmable device in communication with a positioning system for placing a wafer relative to a chuck to: place the workpiece at a first position on the chuck to determine a first workpiece center location (W₁) with respect to the chuck's center location (E); rotate the workpiece by an angle (θ) in relation to the center location (E) to identify a first counter location (W1′), the distance between W1 and W1′ defining a first Eccentricity (Eccen. #1); relocate the workpiece to a second position at a predefined distance (ΔR) from W1 to thereby identify a second workpiece center location (W2); rotate the workpiece by the angle (θ) in relation to the center location (E) to identify a second counter location (W2′), the distance between W2 and W2′ defining a second Eccentricity (Eccen. #2); calculate the geometric chuck center location (E) as a function of one or more of W1, W2, Eccen. #1 and Eccen. #2.

### BRIEF DESCRIPTION OF THE DRAWINGS

Certain disclosed embodiments will now be described with reference to an exemplary ion implantation system as depicted in the accompanying figures, in which like reference numerals may be used to refer to like elements throughout. It should be understood that the description of these aspects is merely illustrative and nonlimiting. In the following description, for purposes of explanation, numerous specific details are set forth in order to provide a thorough understanding of the present invention. It will be evident to one skilled in the art, however, that the present invention may be practiced without some of these specific details. The drawings include:

FIG. 1 schematically illustrates an environment for implementing an embodiment of the disclosure;

FIG. 2 shows the relative positions of the various geometric centers in an application according to one embodiment of the disclosure;

FIG. 3A illustrates an exemplary embodiment of the disclosure for measuring eccentricity in one embodiment of the disclosure;

FIG. 3B illustrates an embodiment of the disclosure for determining and aligning the workpiece to the center location (E) of an electrostatic chuck;

FIG. 4A is an exemplary process flow for determining eccentricity according to one embodiment of the disclosure;

FIG. 4B is a continuation of FIG. 4A;

FIG. 5A illustrates an exemplary application of an embodiment of the disclosure;

FIG. 5B illustrates a plan view of the wafer centers positioned with respect to the ESC center of FIG. 5A;

FIG. 6 schematically illustrates an auto teach technique for mechanical grip platen according to one embodiment of the disclosure; and

FIG. 7 is a flow diagram of a method to determine eccentricity on an aligner platen according to one embodiment of the disclosure.

### DETAILED DESCRIPTION

In the following description, for purposes of explanation, numerous specific details are set forth in order to provide a thorough understanding of the invention. It will be apparent, however, to one skilled in the art that the invention may be practiced without these specific details. In other instances, structure and devices are shown in block diagram form in order to avoid obscuring the invention. References to numbers without subscripts or suffixes are understood to reference all instances of subscripts and suffixes corresponding to the referenced number. Moreover, the language used in this disclosure has been selected principally for readability and instructional purposes and may not have been selected to delineate or circumscribe the inventive subject matter, resort to the claims being necessary to determine such inventive subject matter. Reference in the specification to “one embodiment” or to “an embodiment” means that a particular feature, structure, or characteristic described in connection with the embodiments is included in at least one embodiment of the invention, and multiple references to “one embodiment” or “an embodiment” should not be understood as necessarily all referring to the same embodiment.

The embodiments described herein are examples and for illustrative purposes. Persons of ordinary skill in the art will recognize that alternative techniques for implementing the disclosed subject matter may be used. Elements of example embodiments may be arranged in different arrangements or combined with elements of different example embodiments. For example, the order of execution of blocks and flow charts may be changed. Some of the blocks of those flowcharts may be changed, eliminated, or combined and other blocks may be added as desired.

As used herein, the term “a computer system” can refer to a single computer or a plurality of computers working together to perform the function described as being performed on or by a computer system. As discussed further below, an “end effector” (EE) is a peripheral device that attaches to a robot's wrist, allowing the robot to interact with a workpiece. End effectors can be mechanical or electromechanical and serve as grippers, process tools, or sensors. End effectors range from simple fingered grippers for grabbing a workpiece to complex sensor systems for robotic inspection. A “load lock” is a vacuum chamber used for loading devices such as semiconductor wafers from ambient air pressure into the main vacuum processing chamber.

A processing instrument performs multiple precision operations on a workpiece. The workpiece is often a substrate having a geometric center. A conventional substrate processing equipment includes a transfer chamber and one or more process modules coupled to the transfer chamber. A substrate transport robot resides in the transfer chamber and moves substrates among the process modules. Each process module implements different operations, such as ion implantation, sputtering, etching, coating, soaking, etc. Production processes used by, for example, semiconductor device manufacturers and materials producers often require precise positioning of substrates in the substrate processing equipment.

The precise position of the substrates is conventionally provided by teaching various geometric locations (i.e., geometric centers) on the substrate to a transport robot. Once the robot is taught the desired positions (e.g., the so-called teach position), then the robot acts automatically to position the subsequent workpieces at that precise location and thereby reduce wafer placement error.

The teaching of substrate holding locations in a transport robot coordinate system of a processing apparatus is either manual or automated. For example, teaching of substrate holding locations is performed through manual control of the robotic end effector (EE) while observing the EE's position relative to the substrate holding station. In another example, the movement of the EE may be automated. Conventional methods for teaching substrate holding locations include physically contacting the end effector with substrate holding station features and measuring torque of the transport robot motors to detect the contact and by detecting the substrate holding station features with through-beam sensors carried by the end effector.

The disclosed embodiments generally provide for the automatic (e.g., without operator intervention) determination of the precise location of substrate processing apparatus (e.g., an electrostatic chuck in a processing chamber) and teaching a substrate transport apparatus the locations so as to provide processing repeatability with respect to the subsequent workpieces. As used herein, the term substrate holding station denotes a substrate holding location within a process module (interchangeably, process chamber) or other suitable substrate holding location within the substrate processing apparatus such as, for example, a Load Port (LP), a load lock, a buffer station, etc. While the disclosed embodiments are illustrated in relation to wafer processing for ion implantation, it should be appreciated that the disclosed principles are not limited thereto and may be applied equally to any robotic application requiring centering two components.

In certain applications, the disclosed embodiments may leverage existing equipment and devices employed in the substrate processing apparatus such as substrate processing sensors. A workpiece transport system according to the disclosed embodiments may include one or more robots, each having means (e.g., end effectors) to grasp and move the substrate workpiece. The substrate workpiece may be a wafer. The exemplary system may further include one or more load lock stations, vacuum system and a workpiece processing station. The workpiece processing station may comprise a processing chamber which can be used, for example, for ion implantation. In one embodiment, the system includes a control circuitry in communication with a memory circuitry. The memory circuitry may store instructions which may be executed on the control circuitry. The memory circuitry may comprise actual memory, virtual memory or a combination of actual and virtual memory. The memory circuitry may be stored on the system or at a remote server (e.g., for remote execution on the system). The instructions may comprise algorithms (implemented in software or hardware) disclosed herein to move one or more components of the system in order to obtain eccentricity of a workpiece relative to a designated location. In one embodiment, the designated location may be the electrostatic chuck of the process chamber. In another embodiment, the designated location may be an aligner chuck. In still another embodiment, the aligner chuck and the electrostatic chuck may be concentric such that alignment with one of the chucks would ensure alignment with the other.

The exemplary system may further comprise a communication module to allow the control circuitry to engage different parts of the workpiece processing system to execute instructions according to the disclosed algorithms. Thus, the control circuitry may execute instructions and engage EEs to retrieve, move and place a workpiece at different locations according to predefined algorithms disclosed herein. In yet another embodiment, after eccentricities (e.g., Eccen. #1, Eccen. #2) are calculated and the location of the electrostatic chuck center (E) is determined, the instructions teach one or more robots to place the subsequent workpieces with repeatable precision. In addition, the instructions may be further executed to verify the location of each processing transaction. In another embodiment, the instructions may be periodically updated to accommodate for intangible variations due to normal use.

The disclosed principles may be implemented without significant software changes to the existing programming code embedded into the substrate transport apparatus and/or the substrate processing apparatus system controller. For example, aspects of the disclosed embodiment may utilize existing commands associated with the substrate transport apparatus such as the so-called pick and place commands and/or substrate alignment commands. The aspects of the disclosed embodiments are also operational in various environments (e.g., vacuum, atmospheric, inert gas, filtered air) as they require no additional electronic components to be located within the processing environment. The disclosed embodiments do not require the addition of sensors, cameras or other structures within the transport apparatus or the processing chamber. Accordingly, the aspects of the disclosed embodiment provide for decreased machine down time by avoiding process disruption. In addition, the existing processes within the vacuum or atmospheric portion of the system may remain sealed or otherwise isolated from an external environment and undisturbed.

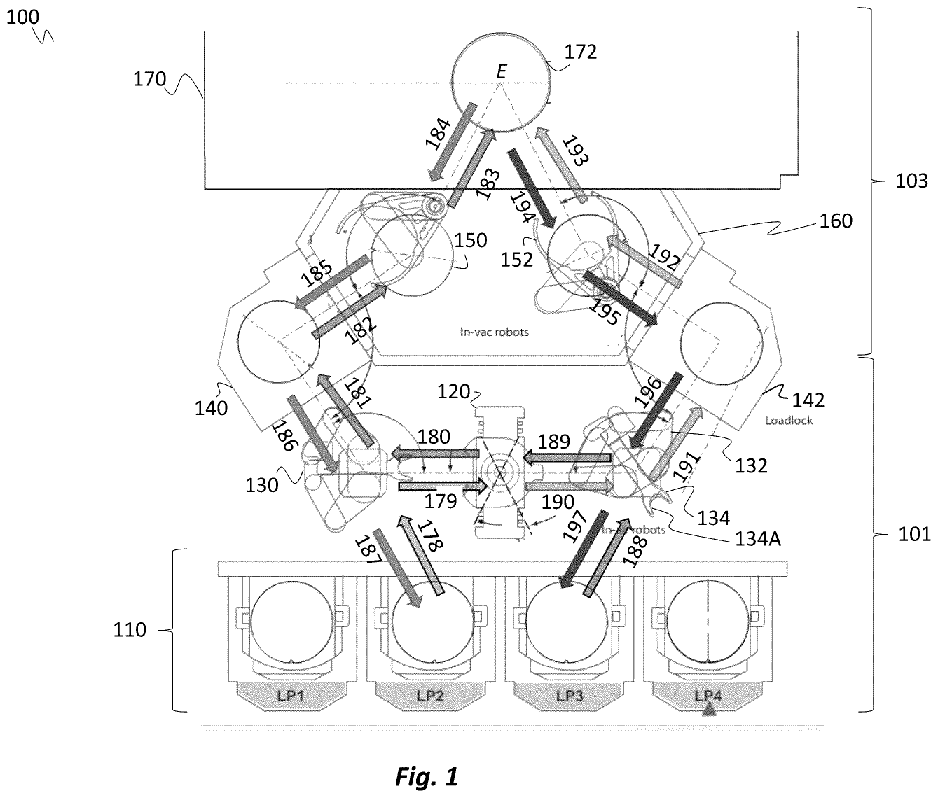

FIG. 1 schematically illustrates an environment for implementing an embodiment of the disclosure. Specifically, FIG. 1 shows substrate processing system 100 having atmospheric side 101 and vacuum side 103. The components of processing system 100 include load ports (LP) 110, aligner 120, load locks (LL) 140, 142 and electrostatic chuck (ESC) 172. In one embodiment, ESC 172 is configured to hold (or clamp) a workpiece wafer (not shown) in place under vacuum environment. ESC 172 is conventionally housed inside process chamber 170. Pre-processed silicon wafers may be stored at load port (e.g., Front Opening Universal Pods “FOUPS”) 110. Load Ports 110 include LP1. LP2, LP3 and LP4. Each LP may store a wafer cassette (e.g., unprocessed substrate) thereon.

Aligner 120 may communicate with robots 130 and 132. Aligner 120 may define a rotary aligner. In one embodiment, aligner 120 may be used to align the workpiece (e.g., an unprocessed wafer) to a desired position for processing. As will be discussed in greater detail, the desired processing position may be the center location (E) of the electrostatic chuck 172. Robots 130 and 132 are on the atmospheric side and are considered atmospheric robots. Robots 130 and 132 are positioned with respect to aligner 120 and LPs 110 so as to retrieve and transport unprocessed wafers (not shown) from the LPs to a respective LLs 140 or 142. Each LL may comprise means to keep a workpiece (i.e., preprocessed workpiece) in place.

In-vacuum robots 150 and 152 are positioned inside transfer chamber 160. Transfer chamber 160 as well as robots 150 and 152 may operate in a vacuum environment. Transfer chamber 160 interfaces the vacuum and atmospheric environment. Each of robots 130, 132, 150 and 152 may further comprise and End Effector (EE). By way of example, FIG. 1 shows EE 134A in connection with robot 134. The EE may comprise one or more mechanical segments positioned at the end of a robotic arm to interact with the environment. In wafer processing, EEs may have a substantially circular receptor having a geometric center and several prongs to grasp the wafer.

In one embodiment, the in-vacuum robots 150, 152 retrieve the wafer workpiece (not shown) from LLs 140, 142, respectively, and rotate, move and position the workpiece inside chamber 170. Wafer processing chamber 170 may comprise, among others, ESC 172 to hold the workpiece stationary by applying voltage. In one application, the ESC 172 receives the workpiece at a horizontal position but moves the workpiece to a vertical position to enable ion implantation. While the disclosure is illustrated with reference to an ESC, it should be appreciated that the embodiments describe herein are also applicable to other types of chucks (e.g., mechanical chucks with physical clamping mechanisms, etc.) without departing from the disclosed principles.

An exemplary wafer handling process on system 100 may include several steps as illustrated by arrows. Robots 130, 134, 150 and 152 may work in tandem and/or simultaneously. An exemplary wafer handling process starts when atmospheric robot 130 retrieves a wafer workpiece (not shown) from LP2 and deposits the workpiece at aligner 120 as illustrated by arrows 178, 179. Aligner 120 comprises an End Effector for wafer handling. Alignment measurement according to the disclosed embodiments may be implemented at aligner 120 as provided below. Next, atmospheric robot 134, through EE 134A, moves the workpiece from aligner 120 to LL 142 as illustrated by arrows 190 and 191.

LLs 140 and 142 operate as vacuum chambers for loading semiconductor wafers and transferring the wafers from ambient air pressure conditions 101 to the processing chamber 170. Processing chamber 172 operates substantially in vacuum conditions. Next, in-vacuum robot 152 transfers the wafer workpiece from LL 142 to process chamber 170 (as indicated by arrows 192, 193) and places the wafer workpiece on ESC 172. Processing chamber 172 implements various processes on the wafer workpiece to form a processed workpiece as schematically indicated by darker arrows. The processed workpiece (not shown) is then transferred by in-vacuum robot 150 from ESC 172 to LL 140 as indicated by arrows 184 and 185. Load Lock 142 pressurizes the processed workpiece in preparation for atmospheric robot 130 to transfer the processed wafer from LL 142 to LP2 as indicated by arrows 186 and 178. The processed workpiece may be stored at LP2.

FIG. 1 further shows a similar operation initiated from LP3. Here, EE 134A of robot 134 transfers an unprocessed wafer workpiece (not shown) from LP3 to aligner 120 as schematically illustrated by arrows 188 and 189. Aligner 120 implements certain steps according to the disclosed algorithms to help align the unprocessed workpiece before it is transported to LL 140 by atmospheric robot 130, which is indicated by arrows 180 and 181. The alignment implemented at aligner 120 may implement certain steps to determine eccentricity and aid in the alignment of the workpiece to that of the ESC 172.

Load Lock 140 prepares the unprocessed workpiece for the upcoming vacuum operation before in-vacuum robot 152 transfers the wafer from LL 140 to ESC 172, which is schematically illustrated by arrows 182, 183. Once processed, in-vacuum robot 152 obtains the processed wafer (not shown) from process chamber 170 and transfers the processed wafer to LL 142, as indicated by arrows 194, 195. Atmospheric robot 132 then transports the processed wafer from Load Lock 142 to LP3 for storage as schematically illustrated by arrows 196 and 197.

The failure to precisely position the workpiece substrate with respect to the ESC Center (E) can result in failed batches and thereby cost both time and material. By way of example, failing to teach the robots their proper positions can cause interference during the wafer transfer process and lead to particle concern. The precise position of the workpiece is generally provided through teaching locations of the process modules to the substrate transport robot. To teach the locations of the process modules and to precisely place workpieces at substrate holding locations, the center of the workpiece must be known. Generally, automatic substrate or wafer centering algorithms require the utilization of a substrate center fixture in order to define the reference substrate location at zero eccentricity relative to, for example, an EE of the robot arm that holds the workpiece. Zero eccentricity is where the location of the substrate center coincides with the geometric center location (E) of electrostatic chuck. Eccentricity offset determination is an important requirement for robot position teaching. Because of the relative movement of the atmospheric robot and the vacuum robot, the disclosed algorithm may be implemented regularly in order to maintain consistency between workpieces.

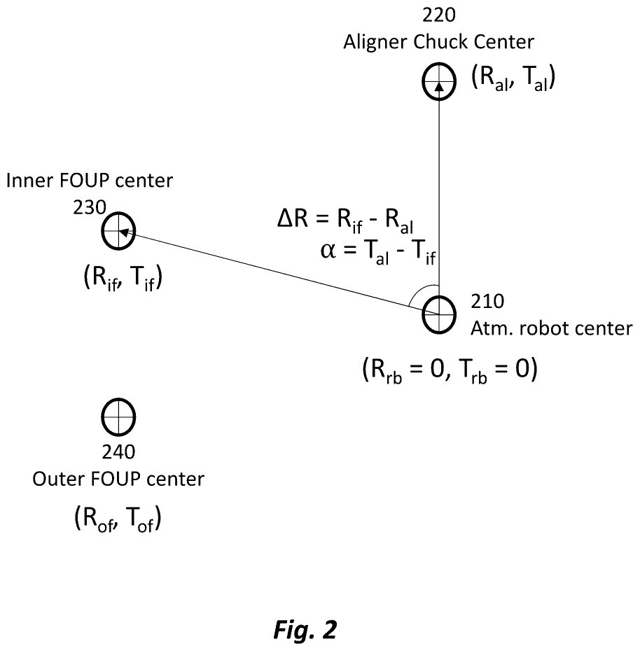

FIG. 2 shows the relative positions of the various geometric centers in an application according to one embodiment of the disclosure. An aspect of robot teaching is to set the relative positions between different stations' centers to match the real physical relative positions. In FIG. 2, the geometric center 210 represents the geometric center of the atmospheric robot (e.g., 130, 134, FIG. 1). Center 220 represents the geometric center of the aligner chuck (e.g., 120, FIG. 1). Location 230 represents the geometric center of the inner FOUP (e.g., LP2, FIG. 1) and center 240 represents the center of outer FOUP 240 (e.g., LP2, FIG. 1). Each geometric center is then identified as a function of its radius, r, and teach position T. As will be discussed below, this information is then used to identify the precise teach position such that the three centers (atmospheric robot base, aligner chuck and inner FOUP) overlap. Once the accurate teach positions T are identified, the accuracy of wafer handling will depend on robot repeatability and the ESC's ability to retain the wafer without relative movement.

Referring now to FIGS. 1 and 2 simultaneously, the geometric center location (E) of ESC 172 at load position may be a pre-defined position and may be adjustable in the horizontal direction. This position is not necessary to be taught to the scan robot as it may be predefined. Aligner 120 may be configured to align wafer center 230 and aligner's chuck (EE) center 220. The robot may be instructed (taught) to align EE center 220 and station center 210 of the atmospheric robot base.

In one embodiment, one or more sensors (fixture assistance) in the atmospheric robot position may be taught such that that EE 220 center and station center 210 overlap. After workpiece alignment, the robot teach position may be adjusted to place the wafer on EE such that the wafer center and EE center are overlapping. Wafer transfer after alignment at aligner 120 assumes that all three geometric centers (i.e., 210, 220 and 230) are concentric and overlapping. If the taught method is accurate, the wafer center and notch orientation at ESC would be aligned and the process will be repeatable. That is, the atmospheric robot at LL, in-vacuum robot at LL, and in-vacuum robot at ESC load position will be in alignment. A wafer transferred by the same robot to multiple stations will be substantially at the same position at each specific station. For example, the wafer is shown to be at the same position after the in-vacuum robot 152 retrieves the workpiece wafer (not shown) from LL 142, place it on ESC 172, retrieve wafer back from ESC 172 and place it back on LL 142. Since there is no movement between the robot, the EE and the wafer, when the wafer is placed back on the LL, it would necessarily be at the same position. It is also assumed that the workpiece wafer does not move relative to the EE during transfer.

Eccentricity may be used according to the disclosed embodiments to concentrically align the workpiece with the geometric center location (E) of the ESC. Once determined, the robot movement may be adjusted to account for the eccentricity value and to align the subsequent workpiece placement on the center location (E). In one embodiment, eccentricity may be determined at the aligner when the wafer is positioned thereon.

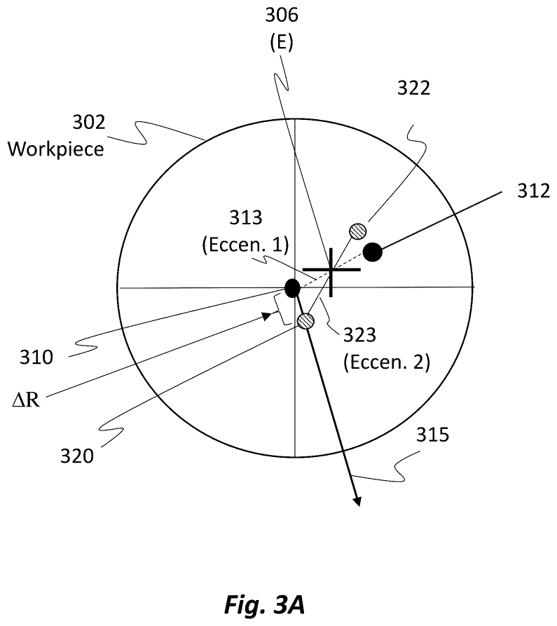

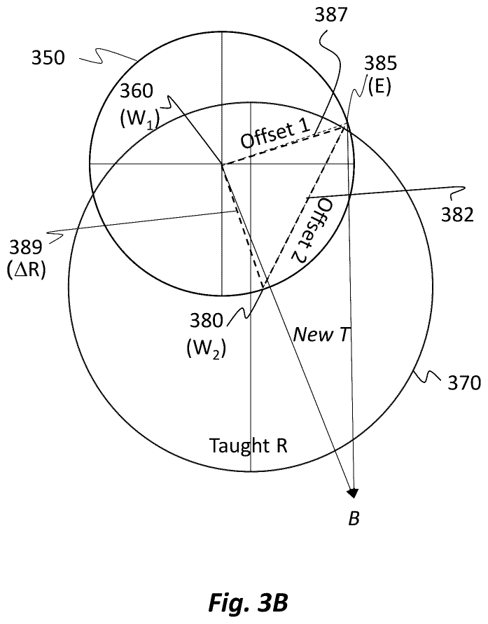

FIG. 3A illustrates an exemplary embodiment of the disclosure for measuring eccentricity according to certain disclosed principles. Specifically, FIG. 3A shows wafer 302 placed on an ESC (not shown). The ESC's geometric center location (E) is marked as location 306. If the wafer's center is positioned concentrically with location 306, then the eccentricity of wafer center after rotating 180 degrees at ESC would be zero as measured at the aligner after the robots transfer the wafer from the ESC back to the aligner. One the other hand, any eccentricity would signal an offset between the wafer and the ESC's center location (E). To determine eccentricity according to one embodiment, the workpiece (not shown) is positioned on the aligner and a first workpiece center location (W₁) is identified as 310. The workpiece may be a substrate or a wafer. The workpiece is then rotated by an angle (θ) (e.g., 180 degrees in FIG. 3) with respect to the aligner center 306 (which is the same as the ESC center, E) and a first counter location 312 (W₁′) is identified. The 180° angle rotation is exemplary and non-limiting of the disclosed principles. A line connecting locations 310 and 312 which crosses chuck center 306 is illustrated as dashed line 313 in FIG. 3A and defines the first eccentricity value (Eccen. #1) as measured at the aligner.

Next, the workpiece is relocated to a second location on the aligner chuck and the subsequent location of the second wafer center location (W₂) is identified as 320. The second location may be determined randomly or may be a predefined location in relation to the first location. In this relocation, the workpiece is placed along the radial axis 315 of workpiece center 310 and is denoted as ΔR in FIG. 3A. Once more the workpiece is rotated by the angle θ (e.g., 180 degrees in FIG. 3) with respect to an axis crossing center location 306 of the aligner and a second counter location (W₂′) is identified as 322. A line connecting the geometric points 320 and 322 which crosses chuck center 306 is illustrated as 323 and is the second eccentricity value (Eccen. #2). As described below, the values W₁, W₂, Eccen. #1 and Eccen. #2 can be used to calculate the geometric center location (E) of the ESC in relation to the workpiece's center.

While eccentricity is a measure of the distance between the wafer center and the chuck center, an offset as used herein is a fraction of the eccentricity value. The offset and eccentricity are related through the angle θ. When 0 is at 180 degrees, the offset value is half of the measured eccentricity value. According to certain disclosed embodiments, the offset values may be used to determine the center location (E).

FIG. 3B illustrates an embodiment of the disclosure for determining and aligning the workpiece to the center location (E). In FIG. 3B, a wafer (not shown) is placed on an ESC (not shown) and its geometric center 360 (W₁) is identified. A first circle whose center is defined as W₁ can have a perimeter 350 and a first radius 387 (Offset1). The geometric center location (E) of ESC center 385 is unknown and resides somewhere along perimeter 350. A second wafer is placed on the ESC (not shown) at a second location with its geometric radial center 380 (W₂). In one embodiment, the ESC center location may be along the perimeter of a second circle 370 with a radial distance 382 (offset2) from second geometric center 380 (W₂). Either of the two intersections (e.g., 385) of first circle 350 and second circle 370 can indicate the center location (E) of the electrostatic chuck. The distance from the center 360 (W₁) to the center 380 (W₂) is shown as intentional offset 389 (ΔR). The triangle formed between locations W₁, W₂ and E can be used to determine the center location (E). Locations of W₁ and W₂ are known as these locations denote the wafer's placements. AR is also known as the distance between W₁ and W₂ (intentional offsets). Thus, the values for Eccen. #1 and Eccen. 2 must be determined before locating E. The following geometric relationships are represented at FIG. 3B:

$$Offset 1 = 0.5 * Eccen . \#1 \qquad ( 1 )$$

$$Offset 2 = 0.5 * Eccen . \#2 \qquad ( 2 )$$

$$\begin{matrix}Angle {W}_{1} {W}_{2} E = {Cos}^{- 1} [ ( Δ {R}^{2} + Offset {2}^{2} - Offset {1}^{2} ) / ( 2 * Δ R * Offset 2 ) ] & ( 3 )\end{matrix}$$

Graphic 3B and equations 4-7 show an exemplary approach to calculate a new in-vacuum robot EE position at ESC. In FIG. 3B, ‘Taught R’ defines the distance between wafer center 1 (W₁ 360) and in-vacuum robot base (B) and New R (Eq. 5) defines the distance between ESC center (E 385) an in-vacuum robot base (B).

$$Angle {EW}_{2} B = π - {W}_{1} {W}_{2} E \qquad ( 4 )$$

$$Triangle {EW}_{2} B has 3 edges : ( Taught R - Δ R ) , Offset 2 , and New R \qquad ( 5 )$$

$$Therefore ,$$

$$New R = Sqrt [ {( Taught R - Δ R )}^{2} + Offset {2}^{2} - 2 * ( Taught R - Δ R ) * + Offset 2 * Cos ( {EW}_{2} B ) ] \qquad ( 6 )$$

$$New T = {Cos}^{- 1} [ ( {( New R )}^{2} + {( Taught R - Δ R )}^{2} - Offset {2}^{2} ) / ( 2 * ( New R ) * ( Taught R - Δ R ) ) \qquad ( 7 )$$

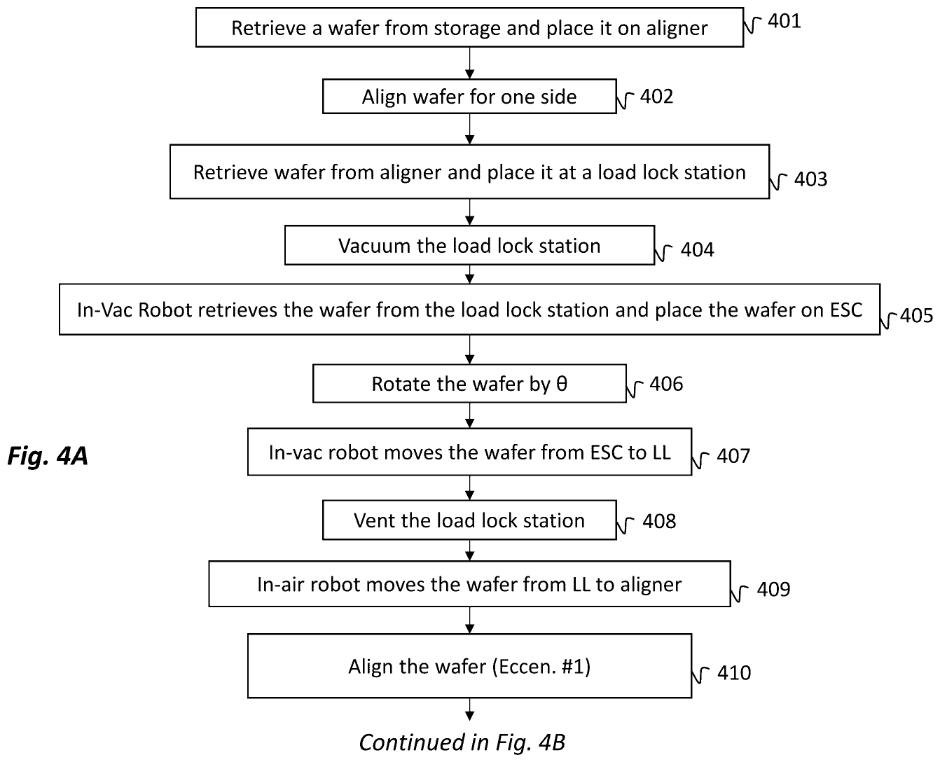

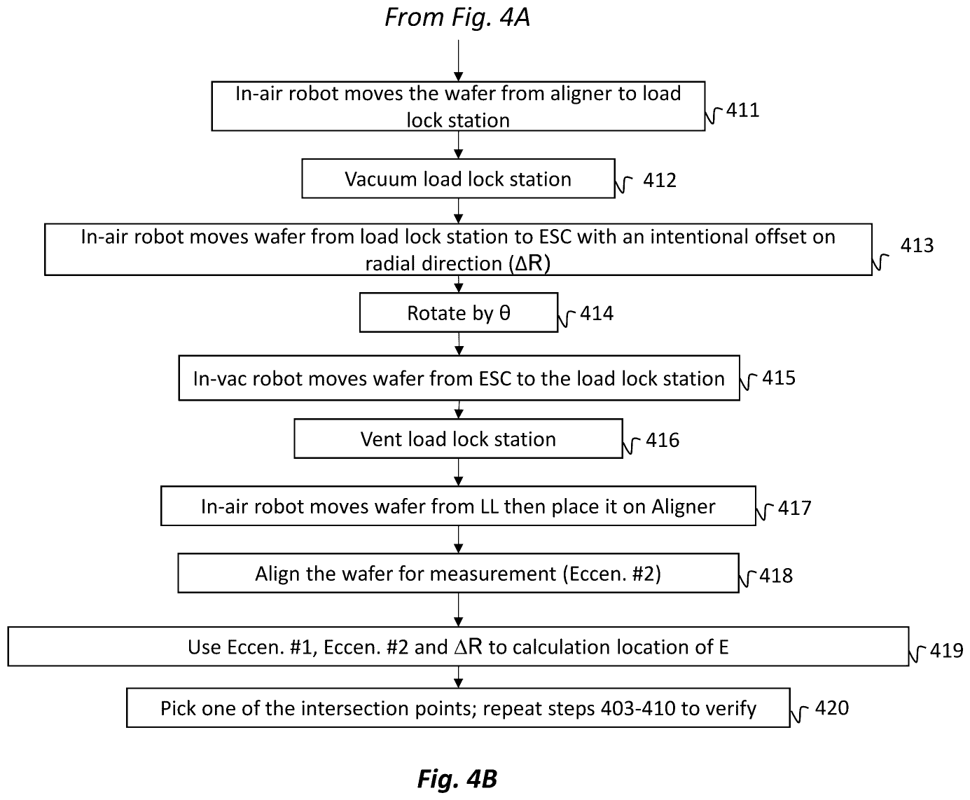

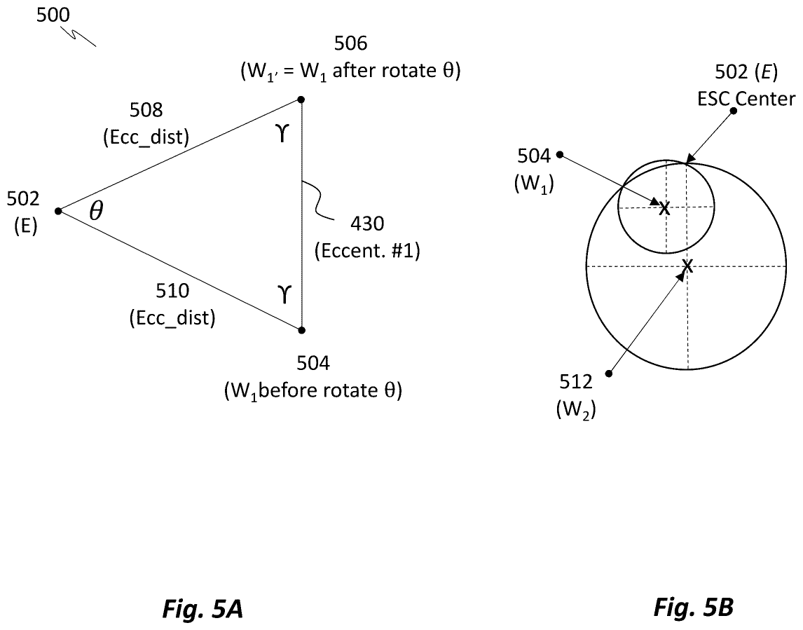

FIG. 4A is an exemplary process flow for determining eccentricity according to one embodiment of the disclosure. The process flow of FIG. 4A may be programmed as an algorithm on software and may be implemented on substrate processing system 100. The algorithm helps determine two eccentricities formed by positioning the wafer on the chuck (i.e., Eccen. #1 and Eccen. #2) at two different positions. These two locations are then used along with geometric relationships discussed above to determine the location of E as illustrated in relation to FIG. 5A. In the exemplary embodiments of FIGS. 4A and 4B, the teach steps may use only one side of the processing system. However, both sides of the processing instrument may be used for verification purposes.

The exemplary process flow diagram of FIGS. 4A and 4B will be discussed with simultaneous reference to FIG. 1. It should be noted that while the disclosed principles and the diagram of FIGS. 4A and 4B are illustrated with reference to the ion implantation system of FIG. 1, the disclosed principles are not limited thereto and are equally applicable to other robotic systems that do not necessarily involve substrate processing. The process of FIG. 4 starts at operation 401, when atmospheric robot 130 retrieves a wafer workpiece (not shown) from LP2 and places the wafer on aligner 120. At operation 402, the wafer is aligned for a measurement (operation 410 below), which may be implemented on the left- or the right-hand side of FIG. 1.

At operation 403, atmospheric robot 130 retrieves the wafer from aligner 120 and places the wafer at LL station 140. The LL station is then vacuumed to the desired pressure as shown in operation 404. At operation 405, in-vacuum robot 150 retrieves the wafer from LL station 140 and places the wafer on ESC 172. The ESC is then rotated by θ (e.g., 180) degrees as indicated by operation 406. The rotation angle may be varied without departing from the disclosed principles.

At operation 407, the in-vacuum robot moves the wafer from ESC 170 to load lock station 140. The load lock station is vented to an atmospheric pressure as shown at operation 408. Once pressurized, at operation 409, in-vacuum robot moves wafer from load lock station 140 to aligner 120. At operation 410, the wafer is aligned and Eccen. #1 is measured (referring to FIG. 3A, Eccen. #1 is denoted by location 313). The flow diagram of FIG. 4A continues to FIG. 4B.

At operation 411 (FIG. 4B), atmospheric robot 130 moves the workpiece wafer from aligner 120 to LL station 140. At operation 412, LL station 140 is placed under a predefined vacuum. At operation 413, in-vacuum robot 150 retrieves the wafer from LL station 140 and places the workpiece on ESC 172 with an intentional offset on the radial direction (ΔR). The intentional offset may be recorded for future calculations. The wafer may be then rotated by a predetermined angle (θ). In the exemplary embodiment of FIG. 4B, the rotation angle is 180 degrees as indicated at operation 414. As discussed herein, the rotation angle can be any angle. Next, in-vacuum robot 150 retrieves and places the wafer at the LL station as shown at operation 415. At operation 416, the LL station is pressurized to atmospheric pressure and at operation 417, atmospheric robot 130 moves the wafer from LL station 140 and places the wafer on aligner 120. At operation 418, the wafer is aligned for measurement and its location denoted as Eccen. #2. At operation 419, Eccen. #1 and Eccen. #2 are used to calculate the offset on the radial direction (ΔR) and to calculate the center location (E) of the electrostatic chuck according to the disclosed principles. Finally, at operation 420, one of the two intersection points (i.e., 385 or 386) is selected as the location of the ESC center (E). In an optional application, operations 403-410 may be repeated to verify the calculated ESC center (E) location.

FIG. 5A illustrates an exemplary application of an embodiment of the disclosure where different rotation (θ) angles may be used. FIG. 5B illustrates a plan view of the wafer centers positioned with respect to the ESC chuck of FIG. 5A. As schematically illustrated in FIGS. 4A and 4B, Eccen. #1 and Eccen. #2 may be determined by positioning and repositioning the wafer on a wafer processing system. The value of difference between the 2 placements along the radial direction (ΔR, FIG. 3B) is also known.

In FIG. 5A, the ESC Center is denoted as location 502 (E). The wafer is positioned at location 504 (W₁) which denotes the first wafer center location (i.e., before rotation). The wafer is then rotated by θ degrees to the first counter location 506 (W₁). Given that triangle 500 is an equilateral triangle, sides 508 and 510 (both of which denote the ESC distance) would be equal in size and angles Y would be determined according to the following relationship:

$$ϒ = ( 180 - θ ) / 2 \qquad ( 8 )$$

The following geometric relationship governs the triangle 500:

$$\frac{Eccentricity}{Sin ( θ )} = \frac{ESC\_distance}{Sin ( \frac{π - θ}{2} )} \qquad ( 9 )$$

At any θ rotation, ESC center (E) can be calculated with the above relationships. Additionally, two special relationships may be readily distinguished. First, if θ is 180°, then the eccentricity value is twice the Eccentricity distance (i.e., Eccentricity=2×Ecc_distance). Second, if θ is 60°, then Eccentricity=Esc_distance.

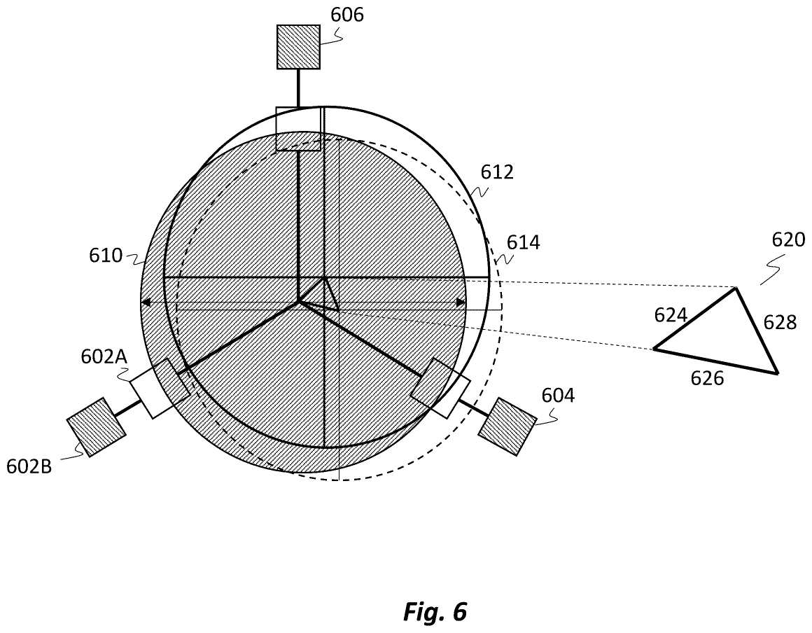

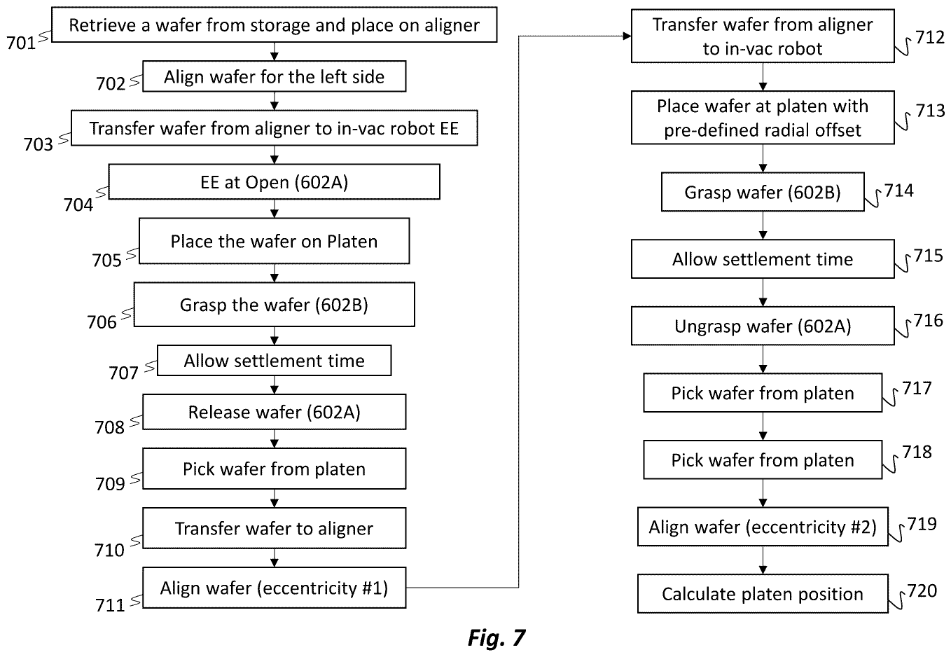

Conventional ESC's use electrostatic force to keep the workpiece (e.g., wafer) stationary. Thus, an ESC may be used to represent the platen. In the FIGS. 6 and 7 the disclosed principles are applied to a mechanical gripper for keeping the workpiece stationary. Thus, FIGS. 6 and 7 reference a platen instead of an ESC.

FIG. 6 schematically illustrates an auto teach technique for mechanical grip platen according to one embodiment of the disclosure. In FIG. 6, structures 602, 604 and 606 illustrate the EE which holds wafer at platen 610. Circle 612 illustrates the first placement of the wafer and circle 614 illustrates the second placement of the wafer. A triangle is illustratively formed between the intersections of circles 610, 612 and 614 which, for ease of illustration, is exploded and illustrated as triangle 620. In triangle 620, side 624 represents eccentricity 1, side 626 represents eccentricity 2 and side 628 illustrates the intentional offset in the radial direction.

FIG. 7 is a flow diagram of a method to determine eccentricity on an aligner platen (interchangeably, platen) according to one embodiment of the disclosure. The flow diagram of FIG. 7 will be described in relation to the illustration of FIG. 6. The process starts at operation 701 when a wafer is retrieved from storage and is placed on an aligner. The wafer is then aligned for the left side (arbitrarily) as noted at operation 702. At operation 703, the wafer is transferred from aligner (not shown) to in-vacuum robot EE (602, 604, 606, FIG. 6). At operation 704, the EE's grasp is opened as schematically illustrated by the open position of all three prongs (e.g., 602A, FIG. 6). For simplicity, only one of the three prongs of the EE is numbered in FIG. 6.

At operation 705, the wafer is placed on the electrostatic chuck's platen and at operation 706 the wafer is grasped by the EE (e.g., 602B, FIG. 6). At operation 707, the wafer is allowed to settle in location. In certain embodiments, the wafer is allowed to settle for about 2-4 seconds. At operation 708, the wafer is released by the EE. At operation 709, the wafer is retrieved from the platen and transferred to aligner as indicated at operation 710. At operation 711, the wafer is aligned to determine the first eccentricity. At operation 712, the wafer is transferred from the aligner to an in-vacuum robot EE (not shown). At operation 713, the wafer is placed on the platen with at a predefined radial offset.

At operation 714, the wafer is once more grasped by the EE (602B, FIG. 6). At operation 715, the wafer is allowed to settle at the EE and at operation 716, the wafer is released by the EE (602A, FIG. 6). At operation 717, the wafer is picked from the platen and transferred onto the aligner (indicated as operation 718). At operation 719, the wafer is aligned with the platen to determine the second eccentricity. Finally, at operation 720 the geometric relationships are used to calculate the center location (E) of the electrostatic chuck.

The following exemplary and non-limiting embodiments are provided to further illustrate the disclosed principles.

Example 1 is directed to a system to position a substantially circular workpiece having a center on an electrostatic chuck of a processing station having a geometric center location (E), the system comprising: one or more memory circuits comprising an executable code; one or more central processing units (CPU) in communication with the memory circuits, the one or more CPUs configured to execute the code, causing the system to: place the workpiece at a first position on the chuck to determine a first workpiece center location (W₁) with respect to the center location (E); rotate the workpiece by an angle (θ) in relation to the center location (E) to identify a first counter location (W₁′), the distance between W₁ and W₁′ defining a first Eccentricity (Eccen. #1); relocate the workpiece to a second position at a predefined distance (ΔR) from W₁ to thereby identify a second workpiece center location (W₂); rotate the workpiece by the angle (θ) in relation to the center location (E) to identify a second counter location (W₂′), the distance between W₂ and W₂′ defining a second Eccentricity (Eccen. #2); calculate the center location (E) as a function of one or more of W₁, W₂, Eccen. #1 and Eccen. #2.

Example 2 relates to the system of Example 1, further comprising executing the code to train one or more mechanical arms to place the workpiece at the center location (E).

Example 3 relates to the system of Example 1, wherein the mechanical arm comprises a robotic arm configured for three-dimensional movement.

Example 4 relates to the system of Example 1, wherein the executed code further causes an end effector of a robotic arm to move the workpiece to the calculated center location (E).

Example 5 relates to the system of Example 1, wherein the workpiece is a wafer and wherein the system comprises an ion implantation system.

Example 6 relates to the system of Example 1, wherein the chuck comprises an electrostatic chuck for receiving the workpiece for ion implantation.

Example 7 relates to the system of Example 1, wherein the center location (E) defines a geometric center of the workpiece.

Example 8 relates to the system of Example 1, W₂ is at a predefined radial distance (ΔR) from W₁.

Example 9 relates to the system of Example 1, wherein W₂ is determined with respect to the chuck center (E).

Example 10 relates to the system of Example 1, wherein the angle (θ) is greater than zero and a value of Offset 1 is determined according to the relationship:

$$Offset 1 = [ Sin ( θ ) / Sin ( ( π - θ ) / 2 ) ] / ( Eccen . \#1 )$$

and wherein the Offset 1 is used to determine the check center (E) location.

Example 11 relates to a non-transitory machine-readable medium with instructions stored thereon that when executed, the instructions cause a programmable device in communication with a positioning system for placing a wafer relative to a chuck to: place the workpiece at a first position on the chuck to determine a first workpiece center location (W₁) with respect to the center location (E) of the chuck; rotate the workpiece by an angle (θ) in relation to the center location (E) to identify a first counter location (W₁′), the distance between W1 and W1′ defining a first Eccentricity (Eccen. #1); relocate the workpiece to a second position at a predefined distance (ΔR) from W₁ to thereby identify a second workpiece center location (W₂); rotate the workpiece by the angle (θ) in relation to the center location (E) to identify a second counter location (W₂′), the distance between W₂ and W₂′ defining a second Eccentricity (Eccen. #2); calculate the center location (E) as a function of one or more of W₁, W₂, Eccen. #1 and Eccen. #2.

Example 12 relates to the medium of Example 11, further comprising executing the code to train one or more mechanical arms to place the workpiece at the geometric chuck center location (E).

Example 13 relates to the medium of Example 11, wherein the mechanical arm comprises a robotic arm configured for three-dimensional movement.

Example 14 relates to the medium of Example 11, wherein the executed code further causes an end effector of a robotic arm to move the workpiece to the calculated center location (E) of the chuck.

Example 15 relates to the medium of Example 11, wherein the workpiece is a wafer and wherein the system comprises an ion implantation system.

Example 16 relates to the medium of Example 11, wherein the chuck comprises an electrostatic chuck for receiving the workpiece for ion implantation.

Example 17 relates to the medium of Example 11, wherein the center location (E) further defines a geometric center of the workpiece.

Example 18 relates to the medium of Example 11, W₂ is at a predefined radial distance (ΔR) from W₁.

Example 19 relates to the medium of Example 11, wherein W₂ is determined with respect to the center location (E).

Example 20 relates to the medium of Example 11, wherein the angle (θ) is greater than zero and a value of Offset 1 is determined according to the relationship:

$$Offset 1 = [ Sin ( θ ) / Sin ( ( π - θ ) / 2 ) ] / ( Eccen . \#1 )$$

and wherein the Offset 1 is used to determine the center location (E).

Although embodiments of the invention have been described in language specific to structural features and/or methodological acts, it is to be understood that claimed subject matter may not be limited to the specific features or acts described. Rather, the specific features and acts are disclosed as sample forms of implementing the disclosed principles.

What is claimed is:

1. A system to position a substantially circular workpiece having a center on an electrostatic chuck of a processing station having a geometric center location (E), the system comprising:
one or more memory circuits comprising an executable code;
one or more central processing units (CPU) in communication with the memory circuits, the one or more CPUs configured to execute the code, causing the system to:
place the workpiece at a first position on the chuck to determine a first workpiece center location (W₁) with respect to the center location (E);
rotate the workpiece by an angle (θ) in relation to the center location (E) to identify a first counter location (W₁′), the distance between W₁ and W₁′ defining a first Eccentricity (Eccen. #1);
relocate the workpiece to a second position at a predefined distance (ΔR) from W₁ to thereby identify a second workpiece center location (W₂);
rotate the workpiece by the angle (θ) in relation to the center location (E) to identify a second counter location (W₂′), the distance between W₂ and W₂′ defining a second Eccentricity (Eccen. #2);
calculate the center location (E) as a function of one or more of W₁, W₂, Eccen. #1 and Eccen. #2.

2. The system of claim 1, further comprising executing the code to train one or more mechanical arms to place the workpiece at the center location (E).

3. The system of claim 1, wherein the mechanical arm comprises a robotic arm configured for three-dimensional movement.

4. The system of claim 1, wherein the executed code further causes an end effector of a robotic arm to move the workpiece to the calculated center location (E).

5. The system of claim 1, wherein the workpiece is a wafer and wherein the system comprises an ion implantation system.

6. The system of claim 1, wherein the chuck comprises an electrostatic chuck for receiving the workpiece for ion implantation.

7. The system of claim 1, wherein the center location (E) defines a geometric center of the workpiece.

8. The system of claim 1, W₂ is at a predefined radial distance (ΔR) from W₁.

9. The system of claim 1, wherein W₂ is determined with respect to the chuck center (E).

10. The system of claim 1, wherein the angle (θ) is greater than zero and a value of Offset 1 is determined according to the relationship:
$$Offset 1 = [ Sin ( θ ) / Sin ( ( π - θ ) / 2 ) ] / ( Eccen . \#1 )$$
and wherein the Offset 1 is used to determine the check center (E) location.

11. A non-transitory machine-readable medium with instructions stored thereon that when executed, the instructions cause a programmable device in communication with a positioning system for placing a wafer relative to a chuck to:
place the workpiece at a first position on the chuck to determine a first workpiece center location (W₁) with respect to the center location (E) of the chuck;
rotate the workpiece by an angle (θ) in relation to the center location (E) to identify a first counter location (W1′), the distance between W1 and W1′ defining a first Eccentricity (Eccen. #1);
relocate the workpiece to a second position at a predefined distance (ΔR) from W1 to thereby identify a second workpiece center location (W2);
rotate the workpiece by the angle (θ) in relation to the center location (E) to identify a second counter location (W2′), the distance between W2 and W2′ defining a second Eccentricity (Eccen. #2);
calculate the center location (E) as a function of one or more of W1, W2, Eccen. #1 and Eccen. #2.

12. The medium of claim 11, further comprising executing the code to train one or more mechanical arms to place the workpiece at the geometric chuck center location (E).

13. The medium of claim 11, wherein the mechanical arm comprises a robotic arm configured for three-dimensional movement.

14. The medium of claim 11, wherein the executed code further causes an end effector of a robotic arm to move the workpiece to the calculated center location (E) of the chuck.

15. The medium of claim 11, wherein the workpiece is a wafer and wherein the system comprises an ion implantation system.

16. The medium of claim 11, wherein the chuck comprises an electrostatic chuck for receiving the workpiece for ion implantation.

17. The medium of claim 11, wherein the center location (E) further defines a geometric center of the workpiece.

18. The medium of claim 11, W₂ is at a predefined radial distance (ΔR) from W₁.

19. The medium of claim 11, wherein W₂ is determined with respect to the center location (E).

20. The medium of claim 11, wherein the angle (θ) is greater than zero and a value of Offset 1 is determined according to the relationship:
$$Offset 1 = [ Sin ( θ ) / Sin ( ( π - θ ) / 2 ) ] / ( Eccen . \#1 )$$
and wherein the Offset 1 is used to determine the center location (E).
